(19) United States
(12) Patent Application Publication
(10) Pub. No.: US 2024/0145514 A1
(43) Pub. Date: May 2, 2024

(54) IMAGE SENSOR

(71) Applicant: Samsung Electronics Co., Ltd., Suwon-si (KR)

(72) Inventors: JAESUNG HUR, Suwon-si (KR); HAJIN LIM, Suwon-si (KR); TAEKSOO JEON, Suwon-si (KR); KI JOONG YOON, Suwon-si (KR); JONGMIN JEON, Suwon-si (KR)

(73) Assignee: Samsung Electronics Co., Ltd., Suwon-si (KR)

(21) Appl. No.: 18/237,278

(22) Filed: Aug. 23, 2023

(30) Foreign Application Priority Data
Oct. 31, 2022 (KR) 10-2022-0142731
Jan. 17, 2023 (KR) 10-2023-0006881

(51) Int. Cl. H01L 27/146

(52) U.S. Cl. CPC H01L 27/14634; H01L 27/14636; H01L 27/1469

(57) ABSTRACT

An image sensor includes a first chip and a second chip. The first chip includes a first substrate including photoelectric conversion parts and a back-side insulating layer covering a first surface of the first substrate. The second chip, which is disposed adjacent the first chip, includes circuits configured to drive the first chip. The back-side insulating layer may include a fixed-charge layer, a refractive index adjusting layer, and a capping layer, which are sequentially disposed on the first surface of the first substrate. The refractive index adjusting layer may include a first element, a second element, and oxygen. A conduction band minimum of an oxide of the second element may be higher than a conduction band minimum of an oxide of the first element.

### CROSS-REFERENCE TO RELATED APPLICATIONS

This U.S. non-provisional patent application claims priority under 35 U.S.C. § 119 to Korean Patent Application Nos. 10-2022-0142731 and 10-2023-0006881, filed on Oct. 31, 2022 and Jan. 17, 2023, respectively, in the Korean Intellectual Property Office, the entire contents of which are hereby incorporated by reference.

### BACKGROUND OF THE INVENTION

The present disclosure relates to semiconductor devices, and more particularly image sensors.

An image sensor is a semiconductor device used for converting light to electric signals. Image sensors are often classified into two types: charge-coupled devices (CCD) and complementary metal-oxide-semiconductor (CMOS) devices. A CMOS-type image sensor (CIS) includes a plurality of pixels that are two-dimensionally arranged. Each of the pixels includes a photodiode (PD), which is used to convert incident light to an electric signal.

### SUMMARY

Embodiments of the inventive concept provide an image sensor configured to reduce leakage current.

According to some embodiments of the invention, an image sensor includes a first chip including a first substrate including photoelectric conversion parts. A back-side insulating layer covers a first surface of the first substrate. A second chip is connected directly or indirectly to the first chip, and includes circuits configured to drive the first chip. The back-side insulating layer may include a fixed-charge layer, a refractive index adjusting layer, and a capping layer, which are sequentially disposed on the first surface of the first substrate. The refractive index adjusting layer may include a first element, a second element, and oxygen. A conduction band minimum of an oxide of the second element may be higher than a conduction band minimum of an oxide of the first element.

According to other embodiments of the invention, an image sensor may include a first chip including a first substrate including photodiodes. A back-side insulating layer covers a first surface of the first substrate. A second chip, which is connected to the first chip, includes circuits configured to drive the first chip. A penetration electrode penetrates the first chip and is connected to the second chip. The first chip may further include first connection lines, which are provided on a second surface of the first substrate and are disposed in a first interlayer insulating layer. The second chip may include second connection lines, which are provided between a second substrate and the second substrate and the first interlayer insulating layer and are disposed in a second interlayer insulating layer. A bottom surface of the penetration electrode may be connected in common to a top surface of one of the first connection lines and a top surface of one of the second connection lines. The back-side insulating layer includes a fixed-charge layer, a refractive index adjusting layer, and a capping layer, which are sequentially disposed on the first surface of the first substrate. The refractive index adjusting layer may include a first element, a second element, and oxygen. An atomic percentage of the second element in the refractive index adjusting layer may range from about 2 at % to about 6 at %.

According to other embodiments of the inventive concept, an image sensor includes a first chip including a pixel region, a pad region, and an optical black region between the pixel region and the pad region. A second chip, which is in contact with a surface of the first chip and includes circuits configured to drive the first chip. The first chip may include a first substrate, a back-side insulating layer on the first substrate, a device isolation portion defining unit pixels in the first substrate, photoelectric conversion parts disposed in the substrate, in respective ones of the unit pixels, transfer gates disposed on a first surface of the first substrate, a first interlayer insulating layer between the first substrate and the second chip, and a first connection line in the first interlayer insulating layer. The second chip may include a second substrate and second connection lines, which are provided in a second interlayer insulating layer on the second substrate. The back-side insulating layer may include a fixed-charge layer, a refractive index adjusting layer, and a capping layer, which are sequentially disposed on a second surface of the first substrate. The refractive index adjusting layer may include a first element, a second element, and oxygen. A conduction band minimum of an oxide of the second element may be higher than a conduction band minimum of an oxide of the first element.

### BRIEF DESCRIPTION OF THE DRAWINGS

FIG. 1 is a plan view illustrating an image sensor according to an embodiment of the inventive concept.

FIG. 2A is a sectional view taken along a line A-A′ of FIG. 1.

FIG. 2B is a sectional view taken along a line B-B′ of FIG. 1.

FIGS. 3A and 3B are enlarged views illustrating a portion ‘Q’ of FIG. 2A.

FIGS. 4 to 9 are sectional views, which are taken along the line A-A′ of FIG. 1 to sequentially illustrate steps in a method of fabricating an image sensor, according to an embodiment of the inventive concept.

### DETAILED DESCRIPTION

Example embodiments of the inventive concepts will now be described more fully with reference to the accompanying drawings, in which example embodiments are shown. In this description, ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

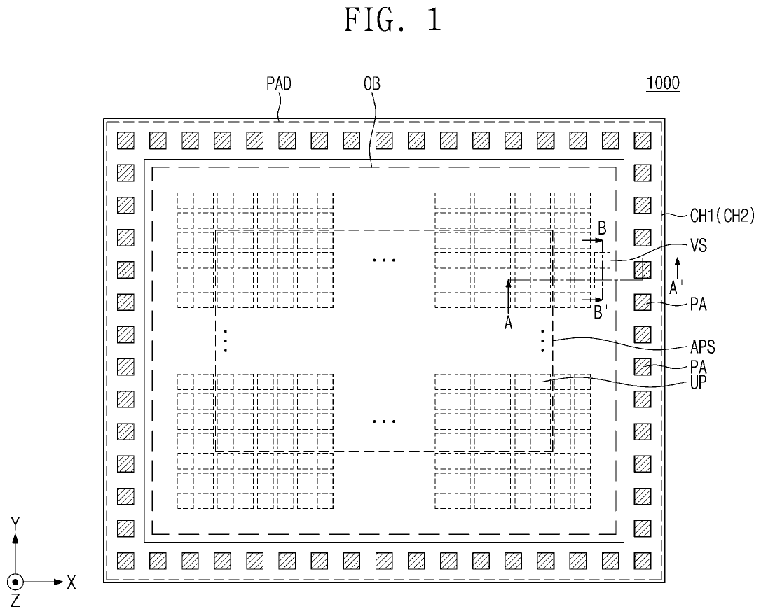

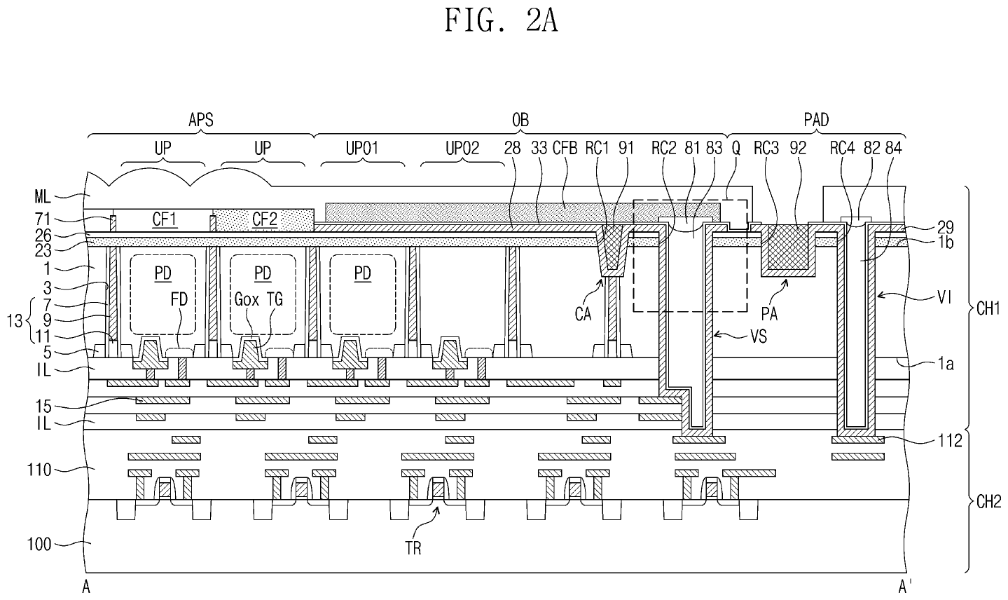

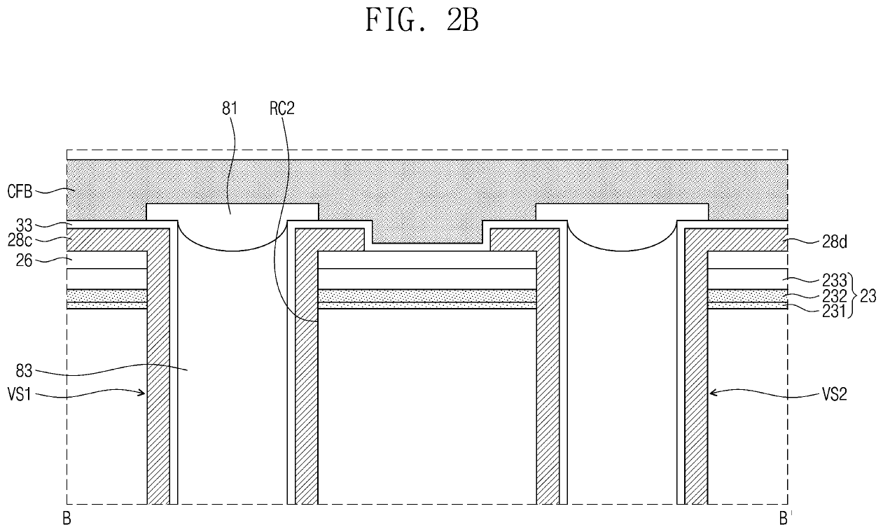

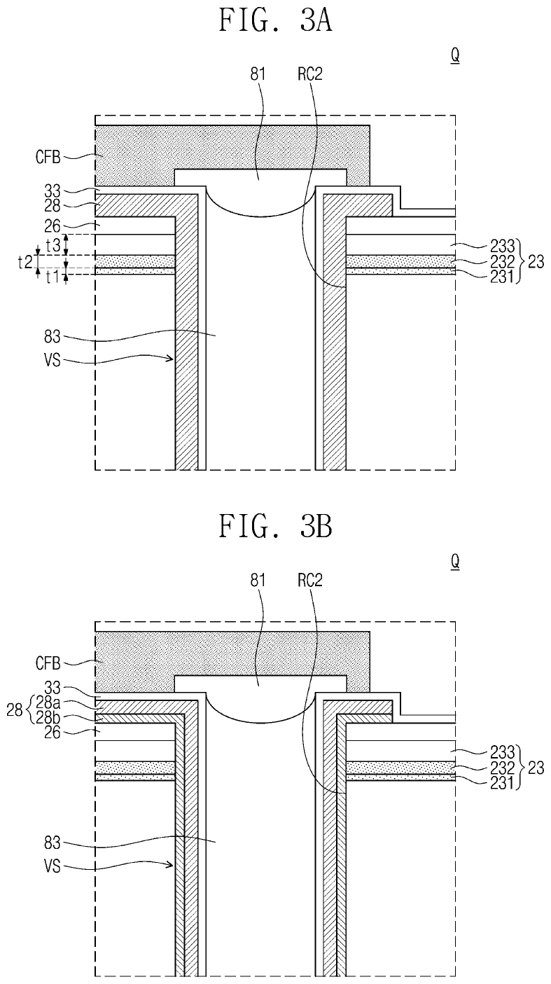

FIG. 1 is a plan view illustrating an image sensor according to an embodiment of the inventive concept. FIG. 2A is a sectional view taken along a line A-A′ of FIG. 1. FIG. 2B is a sectional view taken along a line B-B′ of FIG. 1. FIGS. 3A and 3B are enlarged views illustrating a portion ‘Q’ of FIG. 2A. Referring to FIGS. 1 and 2A, an image sensor 1000 according to the present embodiment comprises a first chip CH1 and a second chip CH2 bonded to each other. The first chip CH1 and a second chip CH2 may be directly connected together (i.e., in contact with each other) or indirectly connected together (e.g., with an intervening layer). It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. The image sensor 1000 may be a back-side light-receiving image sensor. The first chip CH1 may be configured to have an image sensing function. The second chip CH2 may include circuits, which are configured to drive the first chip CH1 or to process or store electrical signals produced by the first chip CH1.

The second chip CH2 may include a second substrate 100, a plurality of transistors TR integrated with the second substrate 100, a second interlayer insulating layer 110 covering the second substrate 100, and second connection lines 112 disposed in the second interlayer insulating layer 110. The transistors TR may be part of a circuit configured to drive the first chip CH1. The second interlayer insulating layer 110 may have a single- or multi-layered structure, in which each layer is formed of at least one of silicon oxide (SiOx), silicon nitride (SiNx), silicon oxynitride (SiNxOy), or a porous insulating material.

The first chip CH1 includes a first substrate 1 including a pad region PAD, an optical black region OB, and a pixel region APS. The optical black region OB and the pad region PAD may be disposed near at least one side of the pixel region APS. As an example, the optical black region OB and the pad region PAD may be disposed to enclose the pixel region APS. The optical black region OB may be disposed between the pad region PAD and the pixel region APS. The first substrate 1 includes a first surface 1a and a second surface 1b, which are opposite to each other. The first substrate 1 may be, for example, a single-crystalline silicon wafer, a silicon epitaxial layer, or a silicon-on-insulator (SOI) wafer. The first substrate 1 may be doped to have a first conductivity type. In an embodiment, the first conductivity type may be p-type.

The pixel region APS includes a plurality of unit pixels UP, which are two-dimensionally arranged in a first direction X and a second direction Y. A second device isolation portions 13 are formed in the pixel region APS to penetrate the first substrate 1 and the first device isolation portions 5, thereby isolating the unit pixels UP from each other. The second device isolation portions 13 may extend into the optical black region OB. First device isolation portions 5 are formed in the first substrate 1 adjacent to the first surface 1a. The second device isolation portion 13 may penetrate the first device isolation portion 5.

The second device isolation portion 13 includes a conductive pattern 9 disposed in a trench 3, an isolation insulating layer 7 enclosing the side or at least a side surface of the conductive pattern 9, and a gapfill insulating pattern 11 interposed between the conductive pattern 9 and the first surface 1a of the first substrate 1. The conductive pattern 9 may be formed of or include a conductive material (e.g., metallic materials or doped polysilicon). The isolation insulating layer and gapfill insulating patterns 11 may be formed from or include, for example, a silicon oxide layer.

In each of the unit pixels UP, a photoelectric conversion part PD is disposed in the first substrate 1. As shown in the illustrated embodiments, photoelectric conversion parts PD may also be disposed in the first substrate 1 in the optical black region. The photoelectric conversion part PD may be doped to have, for example, a second conductivity type different from the first conductivity type of the substrate. The second conductivity type may be, for example, n type. An n-type impurity region, which is formed in the photoelectric conversion part PD through a doping process, may form a PN junction, which is used as a photodiode, with a neighboring p-type impurity region of the first substrate 1.

In each of the unit pixels UP, a transfer gate TG may be disposed on the first surface 1a of the first substrate 1. A portion of the transfer gate TG may extend into the first substrate 1. A gate insulating layer Gox may be interposed between the transfer gate TG and the first substrate 1. A floating diffusion region FD is disposed in a portion of the first substrate 1 at a side of the transfer gate TG. The floating diffusion region FD may be an impurity region doped with impurities (e.g., of the second conductivity type).

Light incident to image sensor 1000 may enter into the first substrate 1 through the second surface 1b of the first substrate 1. That is, the image sensor 1000 may be a back-side light-receiving image sensor. Electron-hole pairs may be produced in the PN junction by the incident light. The charge from electrons produced by this process is transferred to the photoelectric conversion part PD. If a voltage is applied to the transfer gate TG, the charge is transferred to the floating diffusion region FD.

The first surface 1a may be covered with a first interlayer insulating layer IL. The first interlayer insulating layer IL may be in contact with the second interlayer insulating layer 110. The first interlayer insulating layer IL may be formed to have a multi-layered structure and may include one or more silicon oxide layers, a silicon nitride layers, a silicon oxynitride layers, and/or porous low-k dielectric layers. First connection lines 15 may be disposed in the first interlayer insulating layer IL. In an embodiment, the first connection lines 15 may be formed of or include a metallic material (e.g., copper). The first connection lines 15 may be electrically connected to each other via contact plugs (not shown), which are disposed in the first interlayer insulating layer IL.

The contact plugs are provided in the first interlayer insulating layer IL to connect some first connection lines 15 to the transfer gates TG of transistors, which are provided in the pixel region APS and on the first surface 1a of the first substrate 1. In an embodiment, some contact plugs may also connect some first connection lines 15 to the floating diffusion region FD or the transfer gate TG. The contact plugs may be formed of a metallic material different from the first connection lines 15. In an embodiment, the contact plugs may be formed of or include tungsten (W). The contact plugs may further include a barrier layer, which is formed of or includes at least one conductive metal nitride (e.g., titanium nitride (TiN), tantalum nitride (TaN), and tungsten nitride (WN)).

In the optical black region OB, incident light is blocked from entering the first substrate 1. As illustrated in the example of FIG. 2A, the second device isolation portions 13 also extend into the optical black region OB to separate (e.g., isolate) a first black pixel UPO1 and a second black pixel UPO2 from each other. In the first black pixel UPO1, there is a photoelectric conversion part PD disposed in the first substrate 1. In the second black pixel UPO2, a photoelectric conversion part PD is not disposed in the first substrate 1. The transfer gate TG and the floating diffusion region FD may be disposed in both of the first and second black pixels UPO1 and UPO2. The first black pixel UPO1 may be used to sense an amount of charges, which are produced from the photoelectric conversion part PD when light is blocked, and in this case, the sensed charge amount may be used as a first reference charge amount. The first reference charge amount may be used as a reference value for comparison with an amount of charge produced in each of the unit pixels UP. The second black pixel UPO2 may be used to sense an amount of charge produced when the photoelectric conversion part PD is absent, and in this case, the sensed charge amount may be used as a second reference charge amount. The second reference charge amount may be used as information to reduce a process noise. Although not shown, reset transistors, selection transistors, and source follower transistors may also be disposed on the first surface 1a of the first substrate 1. A back-side insulating layer 23 and an etch stop layer 26 may be sequentially provided on the second surface 1b of the first substrate 1. The back-side insulating layer 23 and the etch stop layer 26 will be described in more detail below.

In the optical black region OB, a first metal pattern 28 may be disposed on the etch stop layer 26. The first metal pattern 28 may be a portion of an optical black pattern, which is used to prevent light from being incident into the first substrate 1.

In the pixel region APS, a light-blocking grid pattern 71 may be disposed on the etch stop layer 26. The light-blocking grid pattern 71 overlaps with the second device isolation portion 13 and has a grid structure when viewed in a plan view. The light-blocking grid pattern 71 may be formed of or include metallic and/or insulating materials. In an embodiment, the light-blocking grid pattern 71 includes a low refractive index layer, which is formed of or includes an organic material. The low refractive index layer may have a refractive index that is lower than color filters CF1 and CF2. For example, the low refractive index layer may have a refractive index of about 1.3 or lower.

In the pixel region APS, the color filters CF1 and CF2 may be disposed between the light-blocking grid patterns 71. Color filters CF1 and CF2 may be blue, green, or red filters. In the optical black region OB, a bulk color filter CFB may be disposed on the first metal pattern 28. The bulk color filter CFB may be formed of or include, for example, the same material as the blue color filter. The bulk color filter CFB may be a portion of the optical black pattern. A protection insulating layer 33 may be provided between the first metal pattern 28 and the bulk color filter CFB. In alternative embodiments, the protection insulating layer 33 may extend into a space between the color filters CF1 and CF2 and the etch stop layer 26. The protection insulating layer 33 may be formed of or include one or more insulating materials (e.g., high-k dielectric materials). For example, the protection insulating layer 33 may be formed of or include aluminum oxide and/or hafnium oxide.

A conductive contact CA may be disposed on the optical black region OB. A penetration electrode VS and a first capping pattern 81 may be disposed on the optical black region OB of the first substrate 1. The conductive contact CA may be disposed in a first recess region RC1 formed on the optical black region OB. The conductive contact CA may include a portion of the first metal pattern 28, which extends into the first recess region RC1, and a first gapfill conductive pattern 91. The first gapfill conductive pattern 91 may be formed of or include a metallic material different from the first metal pattern 28. For example, the first gapfill conductive pattern 91 may be formed of or include aluminum. The conductive contact CA may be connected to the second device isolation portion 13. During operation, a voltage may be applied to the second device isolation portion 13 through the conductive contact CA.

The penetration electrode VS may be disposed in a second recess region RC2. The penetration electrode VS extends into the first chip CH1 and may be connected to the second chip CH2. The second recess region RC2 may be formed to sequentially penetrate the etch stop layer 26, the back-side insulating layer 23, the first substrate 1, and the first interlayer insulating layer IL. The penetration electrode VS may be connected to both of the first and second connection lines 15 and 112. In an embodiment, a bottom surface of the second recess region RC2 may include a region that exposes a top and/or side surface of two first connection lines 15 and a region that exposes a top surface of a second connection line 112. Accordingly, the bottom surface of the second recess region RC2 may have a stepwise structure.

The penetration electrode VS may include a portion of the first metal pattern 28, which extends into the second recess region RC2, a portion of the protection insulating layer 33, which also extends into the second recess region RC2, and a first gapfill pattern 83 filling a remaining region of the second recess region RC2. A portion of the first metal pattern 28 may be connected to the first connection line 15 and the second connection line 112. The first gapfill pattern 83 may be formed of or include at least one type of insulating material. As an example, the first gapfill pattern 83 may be formed of or include silicon oxide. The first capping pattern 81 is disposed on a top surface of the first gapfill pattern 83. A bottom surface of the first capping pattern 81 may be convex in a downward direction (e.g., toward the first substrate 1). The top surface of the first capping pattern 81 may be substantially flat. The first capping pattern 81 may be formed of or include at least one insulating polymers (e.g., photoresist materials).

A connection electrode VI and a pad contact PA may be disposed on the pad region PAD. The connection electrode VI may be disposed in a fourth recess region RC4. The connection electrode VI may be provided to penetrate the first chip CH1 and may be connected to the second chip CH2. The fourth recess region RC4 may be formed to sequentially penetrate the etch stop layer 26, the back-side insulating layer 23, the first substrate 1, and the first interlayer insulating layer IL. The connection electrode VI may be connected to the second connection line 112. In an embodiment, a bottom surface of the fourth recess region RC4 may be formed to expose the second connection line 112.

The connection electrode VI may include a portion of a second metal pattern 29, which extends into the fourth recess region RC4, a portion of the protection insulating layer 33, which extends into the fourth recess region RC4, and a second gapfill pattern 84 filling a remaining region of the fourth recess region RC4. The first metal pattern 28 and the second metal pattern 29 may be separated from each other near a boundary between the optical black region OB and the pad region PAD.

The second gapfill pattern 84 may be formed of or include at least one insulating material. As an example, the second gapfill pattern 84 may be formed of or include silicon oxide. A second capping pattern 82 may be provided on the second gapfill pattern 84. A bottom surface of the second capping pattern 82 may be convex in a downward direction. A top surface of the second capping pattern 82 may be substantially flat. The second capping pattern 82 may be formed of or include at least one insulating polymer (e.g., a photoresist material).

The pad contact PA may be provided in a third recess region RC3. The pad contact PA may include a portion of the second metal pattern 29, which extends into the third recess region RC3, and a second gapfill conductive pattern 92. The second gapfill conductive pattern 92 may be formed of or include a metallic material different from the second metal pattern 29. As an example, the second gapfill conductive pattern 92 may be formed of or include aluminum. A voltage may be applied to the transistors TR of the second chip CH2 through the pad contact PA and the connection electrode VI. In an embodiment, the pad contact PA may be connected to an external circuit by various techniques known in the art, such as, by way of non-limiting example, a wire bonding method or the like.

The pixel region APS may be covered with a micro lens layer ML. The micro lens layer ML may also be provided on the optical black region OB and the pad region PAD. The micro lens layer ML may not cover the pad contact PA. The micro lens layer ML may have a convex lens shape on each unit pixel UP in the pixel region APS. The micro lens layer ML may have a flat top surface above the optical black region OB.

Hereinafter, the penetration electrode VS, the back-side insulating layer 23, and the etch stop layer 26 will be described in more detail with reference to FIGS. 2B, 3A, and 3B.

The back-side insulating layer 23 may be in contact with the second surface 1b of the first substrate 1. The back-side insulating layer 23 may be a bottom antireflective coating (BARC) layer. In an embodiment, the back-side insulating layer 23 may include a fixed-charge layer 231, a refractive index adjusting layer 232, and a capping layer 233, which are sequentially provided on the first substrate 1.

The fixed-charge layer 231 may be formed of or include a metal oxide layer having a lower relative oxygen content than the relative oxygen content of the stoichiometric ratio for that metal oxide, or may be formed of or include a metal fluoride layer having a lower fluorine content ratio (relative to the metal content) than the fluorine content ratio of the stoichiometric ratio for the metal fluoride. In this case, the fixed-charge layer 231 may have a negative fixed charge. The fixed-charge layer 231 may be formed of or include at least one of metal oxide materials or metal fluoride materials, which contain at least one metallic element of hafnium (Hf), zirconium (Zr), aluminum (Al), tantalum (Ta), titanium (Ti), yttrium (Y), and lanthanum (La). In an embodiment, the fixed-charge layer 231 may be an aluminum oxide layer. A hole accumulation may occur near the fixed-charge layer 231. The fixed-charge layer 231 may effectively reduce a dark current issue and a white spot issue in an image sensor.

The refractive index adjusting layer 232 may be configured to adjust a light propagation path, enabling light, which is incident into the second surface 1b of the first substrate 1, to effectively reach the photoelectric conversion part PD. The refractive index adjusting layer 232 may be a high refractive index layer. In an embodiment, the refractive index adjusting layer 232 may be an oxide layer that contains a first element, a second element, and oxygen. The first element may be a metallic element, and the second element may be another metallic element or a semiconductor element. In an embodiment, the first element may be titanium, and the second element may be at least one of silicon, tantalum, and hafnium. The refractive index adjusting layer 232 may be amorphous.

A conduction band minimum of an oxide of the second element may be higher than a conduction band minimum of an oxide of the first element. An electron affinity of the oxide of the second element may be smaller than an electron affinity of the oxide of the first element.

The atomic percentage of the second element in the refractive index adjusting layer 232 may range from about 2 at % to about 6 at %. In the case where the atomic percentage of the second element in the refractive index adjusting layer 232 is less than 2 at %, structures in the vicinity of the penetration electrodes VS, which are in contact with the refractive index adjusting layer 232, may lead to an increase of a leakage current through the penetration electrodes VS. In the case where the atomic percentage of the second element in the refractive index adjusting layer 232 is greater than 6 at %, the refractive index adjusting layer 232 may have a refractive index that is lower than the value required for an anti-reflection layer. At the wavelength of 450 nm, the refractive index adjusting layer 232 may have a refractive index (n) ranging from about 2.0 to about 2.7. At the wavelength of 450 nm, the refractive index adjusting layer 232 may have an absorption coefficient (k) ranging from about 0.000001 to about 0.001.

The capping layer 233 may include a layer having a lower dielectric constant than the refractive index adjusting layer 232 and the fixed-charge layer 231. In an embodiment, the capping layer 233 may be formed of or include silicon oxide.

A thickness t1 of the fixed-charge layer 231 may be smaller than a thickness t2 of the refractive index adjusting layer 232. A thickness t3 of the capping layer 233 may be larger than the thickness t2 of the refractive index adjusting layer 232. As an example, the thickness t2 of the refractive index adjusting layer 232 may be about 2 to 4 times the thickness t1 of the fixed-charge layer 231. The thickness t3 of the capping layer 233 may be about 1.5 to 3 times the thickness t2 of the refractive index adjusting layer 232.

The etch stop layer 26 may be formed of or include a material having a higher dielectric constant than the capping layer 233. As an example, the etch stop layer 26 may include a hafnium oxide layer.

In an embodiment, a plurality of penetration electrodes VS may be provided, as shown in FIG. 2B. In an embodiment, the penetration electrode VS may include a first penetration electrode VS1 and a second penetration electrode VS2. The first metal pattern 28c of the first penetration electrode VS1 and the first metal pattern 28d of the second penetration electrode VS2 may be separated from each other, but the refractive index adjusting layer 232 may be in common contact with them. In such a configuration, if a potential barrier between the refractive index adjusting layer 232 and the first metal patterns 28c and 28d is low, a leakage current through the refractive index adjusting layer 232 may be increased. In particular, if the refractive index adjusting layer 232 includes or is formed of the same metal element as the first metal pattern 28, the leakage current may be greatly increased.

According to an embodiment of the inventive concept, by adding the second element into the refractive index adjusting layer 232, it may be possible to increase a potential barrier between the refractive index adjusting layer 232 and the first metal pattern 28 and thereby to reduce a leakage current. Furthermore, the refractive index of the refractive index adjusting layer 232 may be unchanged, and thus, it may be possible to realize an image sensor with high quantum efficiency.

The first metal pattern 28 may include at least one of metal nitride layers (e.g., TiN, TaN, and WN layers), a titanium layer, or a tungsten layer. As an example, the first metal pattern 28 may have a structure, in which a titanium layer and a tungsten layer are sequentially stacked. In an embodiment, the first metal pattern 28 may include a metal nitride layer 28b and a metal layer 28a. In an embodiment, the metal nitride layer 28b may be a TiN layer, and the metal layer 28a may be a layer in which a titanium layer and a tungsten layer are sequentially stacked.

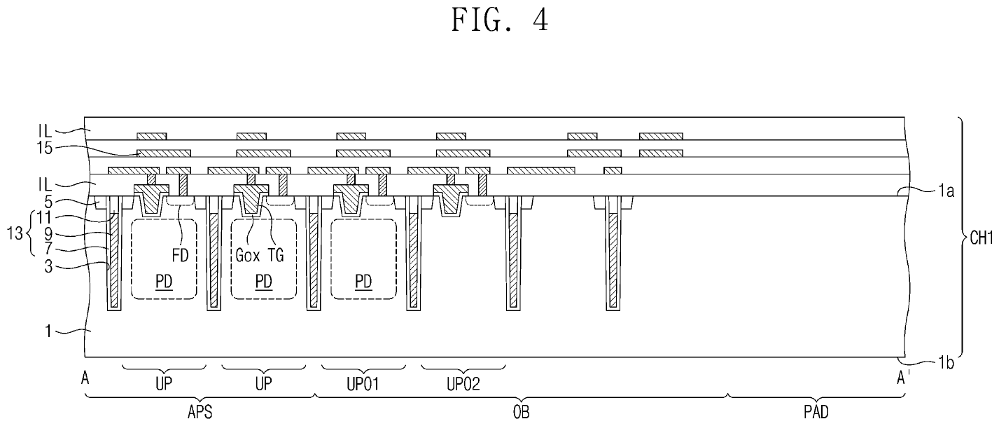

FIGS. 4 to 9 are sectional views, which are taken along the line A-A′ of FIG. 1 to sequentially illustrate steps in a method of fabricating an image sensor, according to an embodiment of the inventive concept.

Referring to FIG. 4, the first chip CH1 may be fabricated in part by forming the photoelectric conversion part PD using an ion implantation process on the first substrate 1, which includes the pixel region APS, the optical black region OB, and the pad region PAD. The first device isolation portion 5 may be formed in the first surface 1a of the first substrate 1 to define active regions. The first device isolation portion 5 may be formed by a shallow trench isolation (STI) process. The trenches 3 may be formed by partially etching the first device isolation portion 5 and the first substrate 1. In the pixel region APS and the optical black region OB, the trenches 3 may delimit the unit pixels UP and the black pixels UPO1 and UPO2. In an embodiment, the trenches 3 may not be formed in the pad region PAD.

The isolation insulating layer 7 may be conformally formed on the entire first surface 1a of the first substrate 1, a conductive material may be formed to fill the trenches 3, and an etch-back process may be performed on the conductive material to form the conductive patterns 9 in the trenches 3, respectively. The gapfill insulating patterns 11 may be formed on the conductive patterns 9, and the isolation insulating layer 7 on the first surface 1a may be removed to expose the first surface 1a. As a result, the second device isolation portion 13, which includes the conductive patterns 9, the isolation insulating layer 7, and the gapfill insulating patterns 11, may be formed.

The gate insulating layer Gox, the transfer gate TG, the floating diffusion region FD, and the first interlayer insulating layer IL may be formed on or in the first surface 1a of the first substrate 1. The first connection line 15 may be formed in the first interlayer insulating layer IL. In an embodiment, the first connection lines 15 may be formed of or include copper. Intermediate contacts (not shown) may be formed to connect the first connection lines 15 to each other.

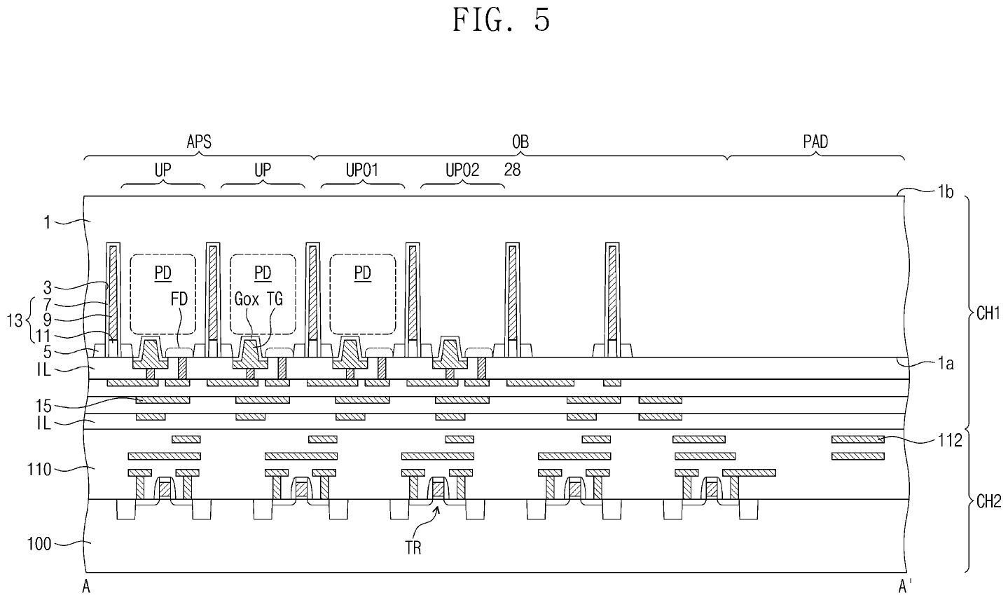

Referring to FIG. 5, illustrating aspects of some flip-chip embodiments, the second chip CH2 is prepared, and then the first chip CH1 is flipped over and attached to the second chip CH2. The first interlayer insulating layer IL is placed to be in contact with the second interlayer insulating layer 110, and then the first chip CH1 is bonded to the second chip CH2 by a thermocompression process or the like.

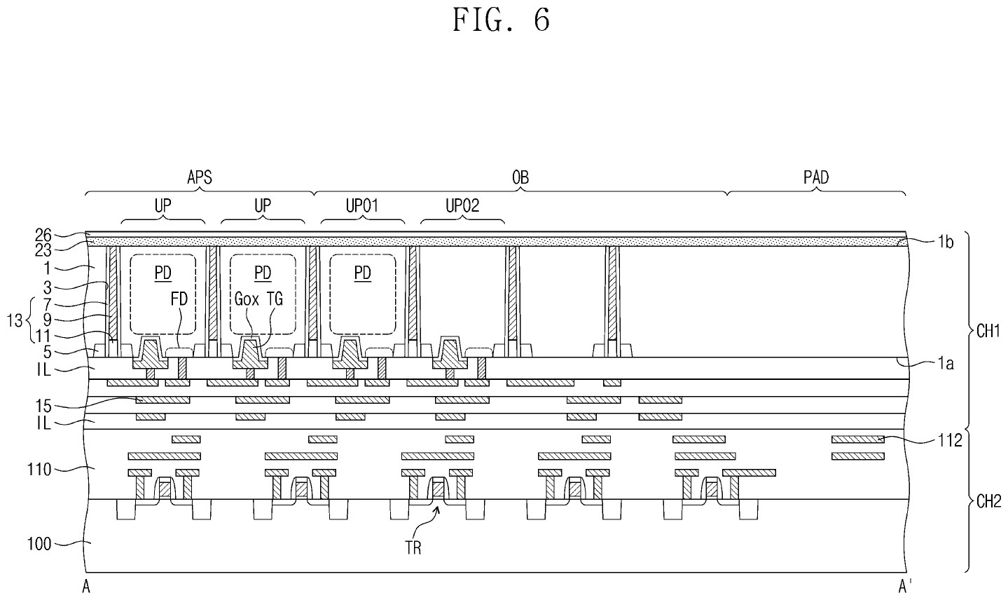

Referring to FIG. 6, a grinding process may be performed on the second surface 1b of the first substrate 1, which is in the state of FIG. 5, to reduce a thickness of the first substrate 1. The grinding process may be performed to expose the conductive pattern 9 of the second device isolation portion 13. The back-side insulating layer 23 may be performed on the second surface 1b of the first substrate 1.

The deposition process of the back-side insulating layer 23 may include a process of sequentially forming the fixed-charge layer 231, the refractive index adjusting layer 232, and the capping layer 233 as described with reference to FIGS. 3A and 3B. The fixed-charge layer 231 may be formed by a chemical vapor deposition process or an atomic layer deposition process.

The refractive index adjusting layer 232 may be formed by an atomic layer deposition process. In an embodiment, the formation of the refractive index adjusting layer 232 may include a first step of injecting a first element and oxygen and a second step of injecting a second element and oxygen. The ratio of the second element in the refractive index adjusting layer 232 may be controlled by adjusting a cycle ratio between the first step and the second step. In an embodiment, the cycle ratio between the first step and the second step may range from 8:1 to 12:1.

As an example, the first element may be titanium, and the second element may be at least one of silicon, tantalum, and hafnium. The second element may lower crystallinity of the refractive index adjusting layer 232, which allows the refractive index adjusting layer 232 to remain in an amorphous state. Since the refractive index adjusting layer 232 is formed to have the amorphous structure, a leakage current through the refractive index adjusting layer 232 may be lowered. In an embodiment, after the deposition of the refractive index adjusting layer 232, a thermal treatment process may be performed at a temperature higher than the temperature used in the deposition. The thermal treatment process may be performed at a temperature of about 200° C. to about 400° C. The thermal treatment process may be a hydrogen annealing process or an oxygen plasma treatment process.

The capping layer 233 may be formed on the refractive index adjusting layer 232. The capping layer 233 may be formed by a chemical vapor deposition method. The deposition temperature at which the capping layer 233 is formed may be higher than the deposition temperature used for deposition of the refractive index adjusting layer 232. As an example, the deposition temperature of the capping layer 233 may range from 300° C. to 400° C.

The etch stop layer 26 may be formed on the back-side insulating layer 23. The etch stop layer 26 may be formed of or include a material having a higher dielectric constant than the capping layer 233. As an example, the etch stop layer 26 may include a hafnium oxide layer.

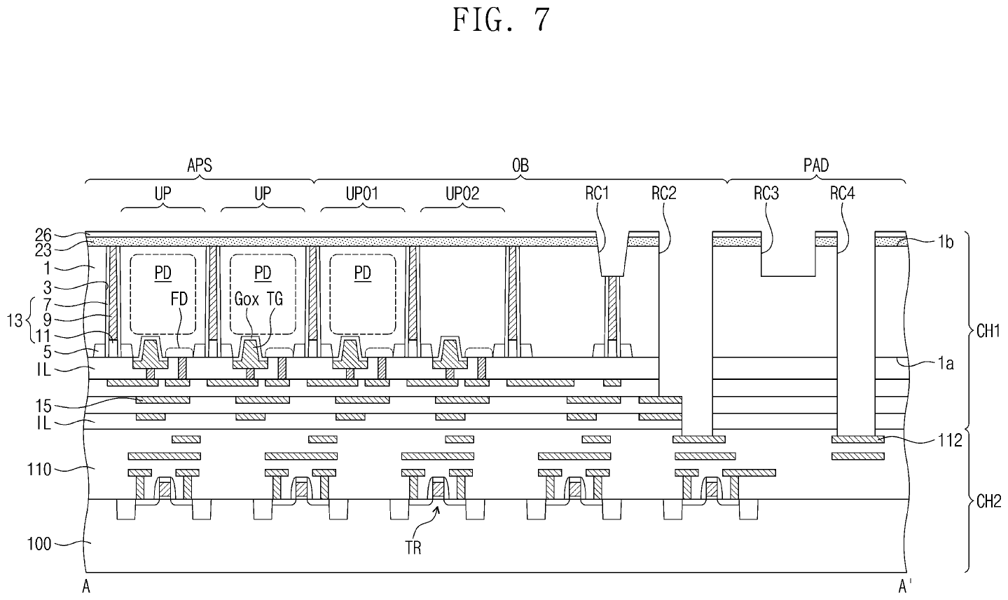

Referring to FIG. 7, the first recess region RC1 and the second recess region RC2 may be formed on the optical black region OB, and the third recess region RC3 and the fourth recess region RC4 may be formed on the pad region PAD. The formation of the first to fourth recess regions RC1 to RC4 may include at least one dry etching process. In an embodiment, the first and third recess regions RC1 and RC3 may be formed together during an etching process, and the second and fourth recess regions RC2 and RC4 may be formed together during another etching process. Alternatively, the first to fourth recess regions RC1 to RC4 may be formed by the same etching process. The second and fourth recess regions RC2 and RC4 may be selectively formed to expose at least one of the first or second connection line 15 or 112.

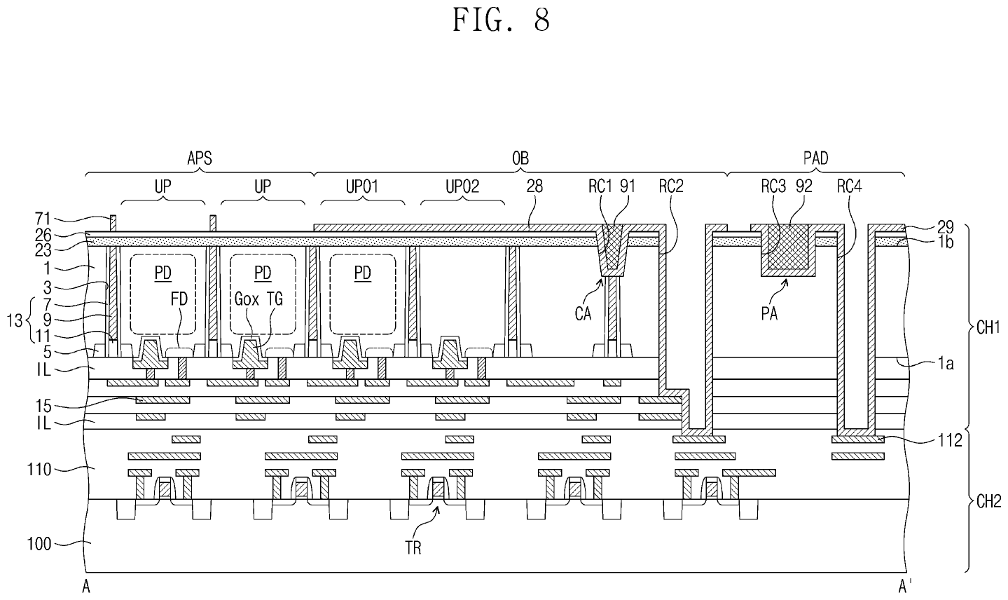

Referring to FIG. 8, a metal layer may be conformally deposited and then may be patterned to form the first metal pattern 28 and the second metal pattern 29. In an embodiment, the formation of the first and second metal patterns 28 and 29 may include sequentially depositing a titanium nitride layer, a titanium layer, and a tungsten layer. The light-blocking grid pattern 71 may be formed on the pixel region APS. The formation of the light-blocking grid pattern 71 may include a patterning process using the etch stop layer 26.

The first gapfill conductive pattern 91 and the second gapfill conductive pattern 92 may be formed to fill the first recess region RC1 and the second recess region RC2, respectively. The first and second gapfill conductive patterns 91 and 92 may be formed of a metallic material different from the first metal pattern 28. In an embodiment, the first and second gapfill conductive patterns 91 and 92 may be formed by a sputtering process. Before the formation of the first and second gapfill conductive patterns 91 and 92, the second and fourth recess regions RC2 and RC4 may be filled with an additional insulating layer, and in this case, a conductive material may not be formed in the second and fourth recess regions RC2 and RC4. Thereafter, the insulating layer may be removed.

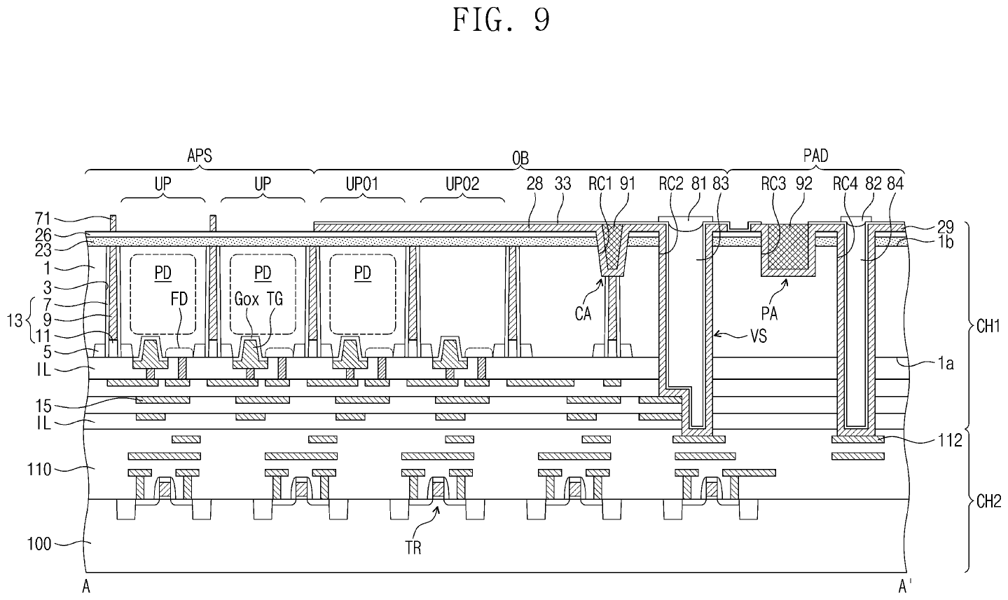

Referring to FIG. 9, the protection insulating layer 33 may be conformally formed on the entire second surface 1b of the first substrate 1. The protection insulating layer 33 may extend into the second and fourth recess regions RC2 and RC4. The protection insulating layer 33 may be formed of or include aluminum oxide or hafnium oxide. The protection insulating layer 33 may be partially removed to expose the second gapfill conductive pattern 92. The exposing of the second gapfill conductive pattern 92 may be performed in the afore-described step, but in an alternative embodiment, the exposing of the second gapfill conductive pattern 92 may be performed after the formation of the micro lens layer ML (described below).

The first gapfill pattern 83 and the second gapfill pattern 84 are formed to fill the second recess region RC2 and the fourth recess region RC4, respectively. In an embodiment, an insulating layer may be formed to fill the second and fourth recess regions RC2 and RC4, and then, a patterning process may be performed on the insulating layer, resulting in the structure of protection insulating layer 33 as shown in FIG. 9. The first capping pattern 81 and the second capping pattern 82 may be formed on the first gapfill pattern 83 and the second gapfill pattern 84, respectively.

Referring back to FIG. 2A, the color filters CF1 and CF2 and the bulk color filter CFB may also be formed. The bulk color filter CFB may be formed when a blue color filter is formed. The micro lens layer ML may be formed on the color filters CF1 and CF2 and the bulk color filter CFB. The micro lens layer ML may be formed on the pixel region APS and the optical black region OB. The protection insulating layer 33 and the micro lens layer ML may be partially removed to expose the second gapfill conductive pattern 92.

According to an embodiment of the inventive concept, an image sensor may include a refractive index adjusting layer, which includes a material having a low conduction band minimum. Accordingly, it may be possible to reduce a leakage current, which may be produced when penetration electrodes are connected to the refractive index adjusting layer.

While example embodiments of the inventive concept have been particularly shown and described, it will be understood by one of ordinary skill in the art that variations in form and detail may be made therein without departing from the spirit and scope of the same.

What is claimed is:

1. An image sensor, comprising:
a first chip comprising a first substrate including photoelectric conversion parts and a back-side insulating layer covering a first surface of the first substrate; and
a second chip connected to the first chip and including circuits configured to drive the first chip,
wherein the back-side insulating layer comprises a fixed-charge layer, a refractive index adjusting layer, and a capping layer, which are sequentially disposed on the first surface of the first substrate,
wherein the refractive index adjusting layer comprises a first element, a second element, and oxygen, and
wherein a conduction band minimum of an oxide of the second element is higher than a conduction band minimum of an oxide of the first element.

2. The image sensor of claim 1, wherein the refractive index adjusting layer comprises an amorphous layer.

3. The image sensor of claim 1, further comprising a penetration electrode that extends into the first chip and is connected to the second chip,
wherein the first chip further comprises first connection lines provided on a second surface of the first substrate and disposed in a first interlayer insulating layer,
wherein the second chip comprises a second substrate and second connection lines provided between the second substrate and the first interlayer insulating layer and disposed in a second interlayer insulating layer, and
wherein a bottom surface of the penetration electrode is connected in common to a top surface of one of the first connection lines and a top surface of one of the second connection lines.

4. The image sensor of claim 3, further comprises a first penetration electrode and a second penetration electrode having the structure of the penetration electrode, and
wherein the refractive index adjusting layer is connected in common to a side surface of the first penetration electrode and a side surface of the second penetration electrode.

5. The image sensor of claim 3, wherein a side surface of the penetration electrode is in contact with the refractive index adjusting layer.

6. The image sensor of claim 5, wherein the penetration electrode comprises a first metal layer and a first metal nitride layer, and
wherein the first metal nitride layer is in contact with the refractive index adjusting layer.

7. The image sensor of claim 3, wherein the penetration electrode extends through the back-side insulating layer.

8. The image sensor of claim 3, wherein the first chip comprises a pixel region, a pad region, and an optical black region between the pixel region and the pad region, and
wherein the penetration electrode is provided in the optical black region.

9. The image sensor of claim 1, wherein an electron affinity of an oxide of the second element is smaller than an electron affinity of an oxide of the first element.

10. The image sensor of claim 1, wherein an atomic percentage of the second element in the refractive index adjusting layer ranges from about 2 at % to about 6 at %.

11. The image sensor of claim 1, wherein the first element is titanium.

12. The image sensor of claim 1, wherein the second element is at least one of silicon, tantalum, and hafnium.

13. The image sensor of claim 1, wherein a refractive index of the refractive index adjusting layer ranges from about 2.0 to about 2.7.

14. The image sensor of claim 1, wherein the first chip further comprises an etch stop layer provided on the back-side insulating layer.

15. An image sensor, comprising:
a first chip including a first substrate comprising photodiodes and a back-side insulating layer covering a first surface of the first substrate;
a second chip connected to the first chip including circuits configured to drive the first chip; and
a penetration electrode that extends into the first chip and is connected to the second chip,
wherein the first chip further comprises first connection lines provided on a second surface of the first substrate and disposed in a first interlayer insulating layer,
wherein the second chip comprises second connection lines provided between a second substrate and the first interlayer insulating layer and disposed in a second interlayer insulating layer,
wherein a bottom surface of the penetration electrode is connected in common to a top surface of one of the first connection lines and a top surface of one of the second connection lines,
wherein the back-side insulating layer comprises a fixed-charge layer, a refractive index adjusting layer, and a capping layer, which are sequentially disposed on the first surface of the first substrate,
wherein the refractive index adjusting layer comprises a first element, a second element, and oxygen, and
wherein an atomic percentage of the second element in the refractive index adjusting layer ranges from about 2 at % to about 6 at %.

16. The image sensor of claim 15, wherein the refractive index adjusting layer is amorphous.

17. The image sensor of claim 15, wherein an electron affinity of an oxide of the second element is smaller than an electron affinity of an oxide of the first element.

18. The image sensor of claim 15, wherein the first element is titanium.

19. The image sensor of claim 15, wherein the second element is at least one of silicon, tantalum, and hafnium.

20. An image sensor, comprising:
a first chip including a pixel region, a pad region, and an optical black region between the pixel region and the pad region; and
a second chip disposed in contact with a surface of the first chip and including circuits configured to drive the first chip,
wherein the first chip comprises:
a first substrate;
a back-side insulating layer on the first substrate;
a device isolation portion defining unit pixels in the first substrate;
photoelectric conversion parts each disposed in the substrate, in respective ones of the unit pixels;
transfer gates disposed on a first surface of the first substrate;
a first interlayer insulating layer between the first substrate and the second chip; and
a first connection line in the first interlayer insulating layer;
wherein the second chip comprises a second substrate and second connection lines disposed in a second interlayer insulating layer on the second substrate,
wherein the back-side insulating layer comprises a fixed-charge layer, a refractive index adjusting layer, and a capping layer that are sequentially disposed on a second surface of the first substrate,
wherein the refractive index adjusting layer comprises a first element, a second element, and oxygen, and
wherein a conduction band minimum of an oxide of the second element is higher than a conduction band minimum of an oxide of the first element.
